(19) United States
(12) Patent Application Publication
(10) Pub. No.: US 2022/0010446 A1
(43) Pub. Date: Jan. 13, 2022

(54) ELECTRODEPOSITION OF NANOTWINNED COPPER STRUCTURES

(71) Applicant: Lam Research Corporation, Fremont, CA (US)

(72) Inventors: Stephen J. Banik, II, Happy Valley, OR (US); Bryan L. Buckalew, Tualatin, OR (US); Justin Oberst, Beaverton, OR (US); Bhuvan Dua, Tualatin, OR (US); Anica Nicole Neumann, Littleton, CO (US); Thomas Anand Ponnuswamy, Sherwood, OR (US)

(21) Appl. No.: 17/309,128

(22) PCT Filed: Oct. 28, 2019
(86) PCT No.: PCT/US2019/058354

§ 371 Date: Apr. 27, 2021

Related U.S. Application Data
(60) Provisional application No. 62/753,846, filed on Oct. 31, 2018.

(51) Int. Cl. C25D 3/38; C25D 5/00; C25D 5/18; C25D 5/10; C25D 5/38; C25D 7/12; C25D 17/06; C25D 21/12

(52) U.S. Cl. CPC C25D 3/38; C25D 5/605; C25D 5/18; C25D 5/617; C25D 21/12; C25D 5/38; C25D 7/123; C25D 17/06; C25D 5/10

(57) ABSTRACT

A copper structure having a high density of nanotwins is deposited on a substrate. Electroplating conditions for depositing a nanotwinned copper structure may include applying a pulsed current waveform that alternates between a constant current and no current, where a duration of no current being applied is substantially greater than a duration of a constant current being applied. In some implementations, the nanotwinned copper structure is deposited by applying a pulsed current waveform followed by a constant current waveform. In some implementations, the nanotwinned copper structure is deposited on a highly-oriented base layer, where an electroplating solution contains an accelerator additive. In some implementations, the nanotwinned copper structure is deposited on a non-copper seed layer. In some implementations, the nanotwinned copper structure is deposited at a relatively low flow rate.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD

Implementations herein relate to methods and apparatuses for electroplating material onto substrates. The substrates are typically semiconductor substrates and the material is typically copper.

### BACKGROUND

Electrochemical deposition processes are well-established in modern integrated circuit fabrication. The transition from aluminum to copper metal line interconnections in the early years of the twenty-first century drove a need for increasingly sophisticated electrodeposition processes and plating tools. Much of the sophistication evolved in response to the need for ever smaller current carrying lines in device metallization layers. Copper lines are formed by electroplating the metal into very thin, high-aspect ratio trenches and vias in a methodology commonly referred to as “damascene” processing (pre-passivation metallization).

Electrochemical deposition is poised to fill a commercial need for sophisticated packaging and multichip interconnection technologies known generally and colloquially as wafer level packaging (WLP) and through silicon via (TSV) electrical connection technology. These technologies present their own very significant challenges due in part to the generally larger feature sizes (compared to Front End of Line (FEOL) interconnects) and high aspect ratios.

Depending on the type and application of the packaging features (e.g., through chip connecting TSV, interconnection redistribution wiring, or chip to board or chip bonding, such as flip-chip pillars), plated features are usually, in current technology, greater than about 2 micrometers and are typically about 5-100 micrometers in their principal dimension (for example, copper pillars may be about 50 micrometers). For some on-chip structures such as power busses, the feature to be plated may be larger than 100 micrometers. The aspect ratios of the WLP features are typically about 1:1 (height to width) or lower, though they can range as high as perhaps about 2:1 or so, while TSV structures can have very high aspect ratios (e.g., in the neighborhood of about 20:1).

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is method of depositing a nanotwinned copper structure. The method includes contacting a surface of a substrate with an electroplating solution, and applying a first current to the substrate when the substrate is contacted with the electroplating solution to deposit a nanotwinned copper structure on the substrate, where the first current comprises a pulsed current waveform that alternates between a constant current and no current.

In some implementations, the nanotwinned copper structure comprises a plurality of (111)-oriented nanotwinned crystal copper grains. In some implementations, a duration of no current being applied in the pulsed current waveform is at least three times longer than a duration of constant current being applied in the pulsed current waveform. In some implementations, the pulsed current waveform alternates between the constant current being applied for a duration between about 0.1 seconds and about 2 seconds, and no current being applied for a duration between about 0.4 seconds and about 6 seconds. In some implementations, the electroplating solution is free of or substantially free of an accelerator additive. In some implementations, the pulsed current waveform includes a plurality of cycles alternating between the constant current and no current to deposit the nanotwinned copper structure having a thickness of at least 5 μm. In some implementations, the method further includes applying a second current to the substrate when the substrate is contacted with the electroplating solution, where the second current comprises a constant current waveform. The first current may be applied to the substrate to deposit a first thickness of at least about 1 μm of the nanotwinned copper structure, and the second current may be applied to the substrate to deposit a second thickness of the nanotwinned copper structure after the first thickness is deposited. In some implementations, the substrate comprises a diffusion barrier layer on which the nanotwinned copper structure is deposited, the diffusion barrier layer having a plurality of columnar grain structures. The electroplating solution may include an accelerator additive. In some implementations, the substrate comprises a copper seed layer on which the nanotwinned copper structure is deposited, the copper seed layer having a plurality of <111> crystal grain structures. The electroplating solution may include an accelerator additive. In some implementations, the substrate comprises a cobalt seed layer on which the nanotwinned copper structure is deposited. In some implementations, contacting the substrate with the electroplating solution occurs at a flow rate of between about 30 cm/s and about 70 cm/s.

Another aspect involves an apparatus. The apparatus includes an electroplating cell for holding an electroplating solution, a substrate holder for supporting a substrate during electroplating, and a power supply for applying current to the substrate during electroplating. The apparatus further includes a controller configured with instructions for performing the following operations: contact a surface of a substrate with the electroplating solution, and apply a first current to the substrate when the substrate is contacted with the electroplating solution to deposit a nanotwinned copper structure on the substrate, where the first current comprises a pulsed current waveform that alternates between a constant current and no current.

In some implementations, a duration of no current being applied in the pulsed current waveform is at least three times longer than a duration of constant current being applied in the pulsed current waveform. In some implementations, the electroplating solution is free of or substantially free of an accelerator additive. In some implementations, the controller is further configured with instructions for performing the following operation: apply a second current to the substrate when the substrate is contacted with the electroplating solution, where the second current comprises a constant current waveform. In some implementations, the substrate comprises a base layer on which the nanotwinned copper structure is deposited, the base layer being a diffusion barrier layer having a plurality of columnar grain structures or a copper seed layer having a plurality of <111> crystal grains.

These and other aspects are described further below with reference to the drawings.

### BRIEF DESCRIPTION OF THE DRAWINGS

FIG. 1 shows a cross-section scanning electron microscopy (SEM) image of a copper pillar with a high density of nanotwinned grain structures.

FIG. 2 shows a cross-section SEM image of a copper pillar with a low density of nanotwinned grain structures.

FIG. 3 shows a flow diagram of an example method of depositing a nanotwinned copper structure according to some implementations.

FIGS. 4A-4C show cross-sectional schematic diagrams of copper grain structures in a sequence for forming nanotwins during electroplating according to some implementations.

FIG. 5A shows a plot of applied current as a function of time in a pulsed current waveform for depositing a nanotwinned copper structure according to some implementations.

FIG. 5B shows a plot of applied current as a function of time in a pulsed current waveform followed by a constant current waveform for depositing a nanotwinned copper structure according to some implementations.

FIGS. 6A-6C show cross-section SEM images of 30 μm thick copper pillars deposited using a pulsed waveform for 3 μm followed by a constant current waveform, a pulsed waveform for 1 μm followed by a constant current waveform, and a constant current waveform only according to some implementations.

FIG. 7 shows a cross-section SEM image of a copper redistribution layer with a high density of nanotwinned grain structures.

FIG. 8A shows a cross-sectional schematic of a nanotwinned copper structure deposited on a base layer according to some implementations.

FIG. 8B shows a cross-section transmission electron microscopy (TEM) image of a nanotwinned copper structure deposited on a highly columnar diffusion barrier layer.

FIG. 9 shows a cross-section SEM image of a copper redistribution layer having a high density of nanotwinned grain structures on a cobalt seed layer.

FIG. 10 shows a schematic diagram of an example of an electroplating cell in which electroplating may occur according to some implementations.

FIG. 11 shows a schematic of a top view of an example electrodeposition apparatus according to some implementations.

FIG. 12 shows a schematic of a top view of an alternative example electrodeposition apparatus.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

### Introduction

Advancements in materials, processing, and equipment have led to innovations in packaging technologies. Wafer level packaging, bumping, redistribution layers, fan out, and through-silicon vias are some of the techniques employed in advanced packaging. In many cases, integrated circuit packaging involves wafer level packaging (WLP), which is an electrical connection technology that employs relatively large features, typically on the scale of micrometers. Examples of WLP features include redistribution wiring, bumps, and pillars. Such features in WLP applications and advanced packaging applications may include copper. Copper is generally used in metal connecting devices because of its high electrical conductivity, thermal transferring ability, and low cost.

In a typical electroplating process, a substrate is cathodically biased and is brought in contact with an electroplating solution containing ions of a metal that is being plated. Ions of the metal are electrochemically reduced at the surface of the substrate to form a metal layer. The metal layer may be a copper layer. Electroplated copper of the present disclosure may be used in wafer level packaging applications and advanced packaging applications.

### Nanotwinned Copper

Crystal defects may be introduced in a material that can influence mechanical, electrical, and optical properties of the material. Twinning may occur in a material where two parts of a crystal structure are symmetrically related to one another. In a face-centered cubic (FCC) crystal structure, of which copper is included, coherent twin boundaries may be formed as (111) mirror planes from which the normal stacking sequence of (111) planes is reversed. In other words, adjacent grains are mirrored across coherent twin boundaries in a layered (111)-structure. Twins grow in a layer-by-layer manner extending along a lateral (111) crystal plane where a twin thickness is on the order of nanometers, hence the name “nanotwins.” Nanotwinned copper (nt-Cu) exhibits excellent mechanical and electrical properties and may be used in a wide variety of applications in wafer level packaging and advanced packaging designs.

Compared to copper having conventional grain boundaries, nanotwinned copper possesses strong mechanical properties including high strength and high tensile ductility. Nanotwinned copper also demonstrates high electrical conductivity, which may be attributable to the twin boundary causing electron scattering that is less significant compared to a grain boundary. Furthermore, nanotwinned copper exhibits high thermal stability, which may be attributable to the twin boundary having excess energy on the order of magnitude lower than that of a grain boundary. In addition, nanotwinned copper enable high copper atom diffusivity, which is useful for copper-to-copper direct bonding. Nanotwinned copper also shows high resistance to electromigration, which may be a result of twin boundaries slowing down electromigration-induced atomic diffusion. Nanotwinned copper demonstrates a strong resistance to seed etch that may be important in fine-line redistribution layer applications. Nanotwinned copper also shows low impurity incorporation, which results in fewer Kirkendall voids as a result of soldered reactions with the nanotwinned copper.

In some implementations, nanotwinned copper enables direct copper-copper bonding. Such copper-copper bonding may occur at low temperatures, moderate pressures, and lower bonding forces/times. Typically, deposition of copper structures results in rough surfaces. In some implementations, prior to copper-copper bonding, electrodeposition of nanotwinned copper may be followed by an electropolishing process to achieve smooth surfaces. With the smooth surfaces, the nanotwinned copper structure may be used in copper-copper bonding with shorter bonding times, lower temperatures, and fewer voids.

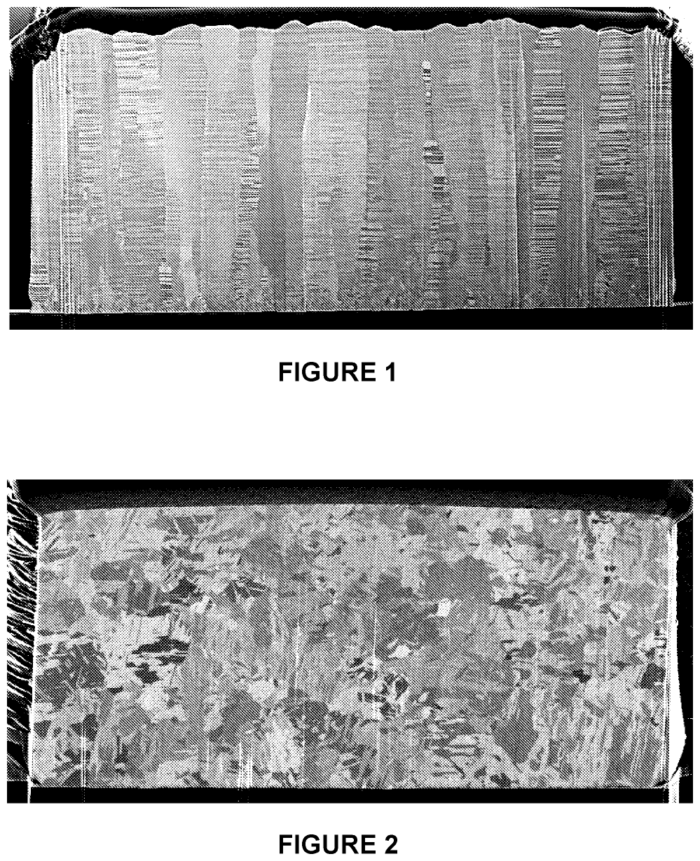

FIG. 1 shows a cross-section SEM image of a copper pillar with a high density of nanotwinned grain structures. The presence of nanotwinned grain structures can be observed using any suitable microscopy technique such as an electron microscopy technique. The copper pillar includes several submicron-sized grains that are tall and columnar. For example, the grains may have a diameter between about 1 nm and about 1000 nm. As shown in the SEM image in

FIG. 1, the grains are highly columnar and have a high density of grown-in nanotwins. The highly columnar grains may have a relatively large diameter and relatively large height. For example, an average diameter of the highly columnar grains may be between about 0.2 μm and about 20 μm, and an average height of the highly columnar grains may be between about 1 μm and about 200 μm.

A high density of nanotwins is observed by a high density of twin lamellar structures parallel to each other or at least substantially parallel to each other. A pair of adjacent dark and light lines may constitute a nanotwin, and nanotwins may stack along a stacking direction (e.g., along a [111] crystal axis) to form a grain. The nanotwins may be formed parallel to the (111) surface of the copper pillar. An average lamella thickness varies from about a few nanometers to about hundreds of nanometers. For example, an average lamella thickness can be between about 5 nm and about 100 nm. An average length of the lamellar structures may vary from tens of nanometers to tens of microns hundreds of nanometers. For example, an average lamella length can be as small as 50 nm and as large as 20 μm, or the entire width of a columnar grain.

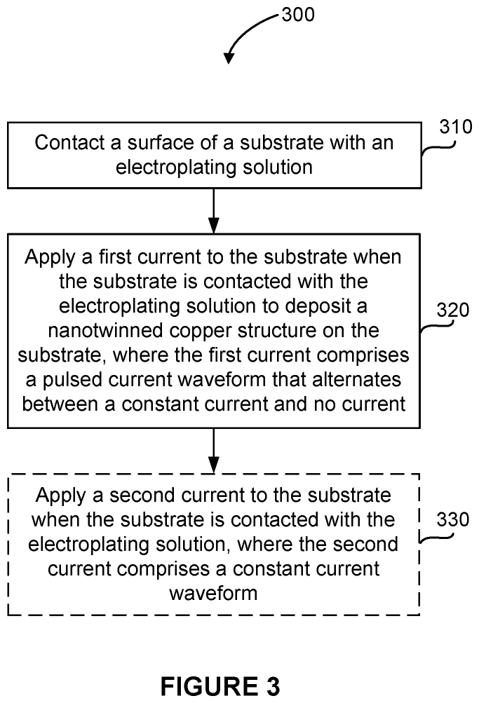

FIG. 2 shows a cross-section SEM image of a copper pillar with a low density of nanotwinned grain structures. The copper pillar includes several submicron-sized grains, where the grains are randomly oriented. A low density of nanotwins is observed by a low density of twin lamellar structures parallel to each other or at least substantially parallel to each other. In other words, the low density of nanotwins is observed by an absence of nanotwins stacked along a stacking direction.

Nanotwinned copper structures may be characterized by a plurality of (111)-oriented crystal copper grains containing a plurality of nanotwins. In some implementations, the plurality of (111)-oriented crystal copper grains contain a high density of nanotwins. As used herein, a “high density of nanotwins” may refer to copper structures having at least several tens or hundreds of nanotwins parallel or at least substantially parallel to each other as observed using suitable microscopy techniques.

The crystal orientation of the crystal copper grains may be characterized using a suitable technique such as electron backscatter diffraction (EBSD) analysis. In some implementations, crystal orientation maps may be displayed in inverse pole figure (IPF) maps. Nanotwinned copper structures may contain primarily (111)-oriented grains.

### Electroplating Conditions for Forming Nanotwinned Copper Structures

Formation of reproducible and high throughput nanotwinned copper structures has been challenging. However, plating conditions in the present disclosure can be controlled to reproducibly electroplate nanotwinned copper structures at an acceptable plating rate to achieve high throughput. Accordingly, copper structures are deposited under plating conditions that result in a high density of nanotwins in the copper structures. Some of the plating conditions include but are not limited to electroplating solution chemistry, crystal structure and orientation of an underlying base layer, and waveform of applied current to the substrate during electroplating. Other plating conditions for depositing nanotwinned copper structures may further include flow conditions of the electroplating solution when contacting the substrate, temperature, and chemical pretreatment such as dipping in suppressor, or cleaning with acetone, acid, piranha solution, or some other cleaning agent.

The present disclosure relates to deposition of copper structures under plating conditions that result in a high density of nanotwins in the copper structures. Such nanotwinned copper structures can be formed by applying a current to a substrate in contact with electroplating solution where the current has a pulsed waveform. The pulsed waveform alternates between a constant current (Iₒₙ) and no current (I_{off}) in a series of cycles, where a duration of no current being applied per cycle is substantially greater than a duration of the constant current being applied. In some implementations, the current density of the constant current being applied is between about 2 A/dm² and about 8 A/dm². In some implementations, the electroplating solution is free of or substantially free of an accelerator additive. Nanotwinned copper structures may be formed by applying a current having a pulsed waveform and then applying a current having a constant current waveform. Furthermore, nanotwinned copper structures may be deposited on highly-oriented base layers of a substrate, where the electroplating solution in contact with the substrate may include an accelerator additive. The highly-oriented base layer may include a diffusion barrier layer having a plurality of columnar grain structures or a copper seed layer having a plurality of <111> crystal grain structures. In some implementations, nanotwinned copper structures may also be deposited on cobalt seed layers. In some implementations, nanotwinned copper structures may be deposited at a low flow rate, such as a flow rate of about 70 cm/s or less.

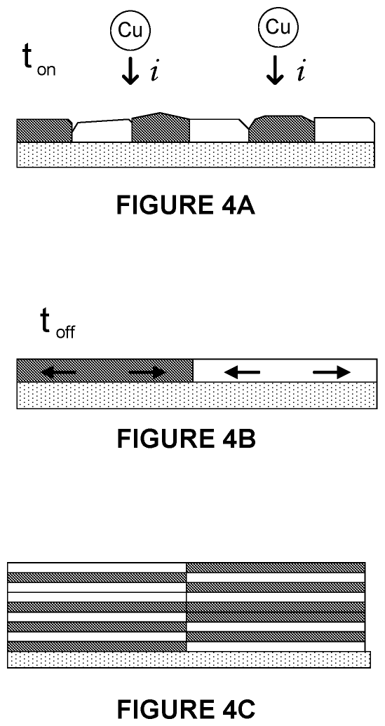

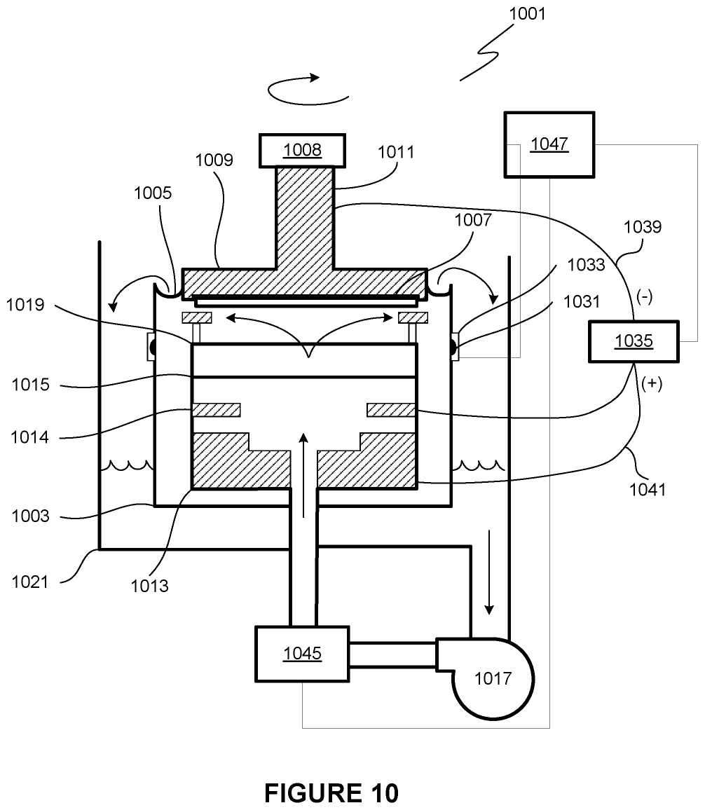

FIG. 3 shows a flow diagram of an example method of depositing a nanotwinned copper structure according to some implementations. The operations in a process 300 may be performed in different orders and/or with different, fewer, or additional operations. The operations in the process 300 may be performed in an electroplating apparatus. The electroplating apparatus may include an electroplating cell configured to hold an electroplating solution while electroplating copper onto a substrate. The electroplating apparatus may further include a substrate holder for supporting a substrate during electroplating and a power supply for applying current to the substrate during electroplating. Examples of electroplating apparatuses are described in FIGS. 10-12, which may be configured to perform the operations of the process 300. One example of an electroplating apparatus is the Sabre® Electroplating System produced by and available from Lam Research Corporation of Fremont, Calif.

At block 310 of the process 300, a surface of a substrate is contacted with an electroplating solution. The substrate and the electroplating solution may be contained or held in a plating chamber. In some implementations, the substrate is immersed in the electroplating solution and is held by a substrate holder or holding fixture. An anode may be disposed in the plating chamber such that the surface of the substrate is separated from the anode during electroplating. The electroplating solution may be flowed into the plating chamber and contact the surface of the substrate.

Control and composition of the electroplating solution used in electroplating copper may be important in the performance of electroplating copper with a high density of nanotwins. Typically, there are many components in a given electroplating solution, which may also be referred to as an electrolyte. For example, the composition of the electroplating solution may include a copper salt, an acid, and organic additives. The copper salt is the copper source for the deposition. Example copper salts include, but are not limited to, copper sulfate, copper methanesulfonate, copper pyrophosphate, copper propanesulfonate, etc. As used herein, the concentration of copper ions reflects the concentration (mass per volume) of copper cations, and does not include the mass of any anions associated with the copper cations. Acid is generally used to control the conductivity of the plating bath. Example acids include, but are not limited to, sulfuric acid and methane sulfonic acid. In some implementations, the electroplating solution contains halide ions that may act as bridges to assist adsorption of certain organic additives onto a substrate surface. Example halide ions include but are not limited to chloride ions, bromide ions, iodide ions, and combinations thereof. In some implementations, the electroplating solution contains complexing agents that can bind with copper ions and form soluble complexes. Example complexing agents include but are not limited to ethylenediaminetetraacetic acid (EDTA), nitrilotriacetic acid (NTA), citric acid, and glutamic acid. Organic additives may be important in achieving a desired metallurgy, film uniformity, defect control, and fill performance. Example organic additives typically include suppressors and accelerators and possibly levelers.

While not wishing to be bound to any theory or mechanism of action, it is believed that suppressors (either alone or in combination with other bath additives) are surface-kinetic polarizing compounds that lead to a significant increase in the voltage drop across the substrate-electrolyte interface, especially when present in combination with a surface chemisorbing halide (e.g., chloride or bromide). The halide may act as a bridge between the suppressor molecules and the substrate surface. The suppressor both (1) increases the local polarization of the substrate surface at regions where the suppressor is present relative to regions where the suppressor is absent, and (2) increases the polarization of the substrate surface generally. The increased polarization (local and/or general) corresponds to increased resistivity/impedance and therefore slower plating at a particular applied potential. It is believed that suppressors are not incorporated into the deposited copper structure, though they may slowly degrade over time. Suppressors are often relatively large molecules, and in many instances they are polymeric in nature (e.g., polyethylene oxide, polypropylene oxide, polyethylene glycol, polypropylene glycol, etc). Other examples of suppressors include polyethylene and polypropylene oxides with S- and/or N-containing functional groups, block polymers of polyethylene oxide and polypropylene oxides, etc. The suppressors can have linear chain structures or branch structures. It is common that suppressor molecules with various molecular weights co-exist in a commercial suppressor solution. Due in part to suppressors' large size, the diffusion of these compounds into a recessed feature is relatively slow.

While not wishing to be bound by any theory or mechanism of action, it is believed that accelerators (either alone or in combination with other bath additives) tend to locally reduce the polarization effect associated with the presence of suppressors, and thereby locally increase the electrodeposition rate. The reduced polarization effect is most pronounced in regions where the adsorbed accelerator is most concentrated (i.e., the polarization is reduced as a function of the local surface concentration of adsorbed accelerator). Example accelerators include, but are not limited to, dimercaptopropane sulfonic acid, dimercaptoethane sulfonic acid, mercaptopropane sulfonic acid, mercaptoethane sulfonic acid, bis-(3-sulfopropyl) disulfide (SPS), and their derivatives. Although the accelerator may become strongly adsorbed to the substrate surface and generally laterally-surface immobile as a result of the plating reactions, the accelerator is generally not incorporated into the deposited copper structure. Thus, the accelerator remains on the surface as copper is deposited. As a recess is filled, the local accelerator concentration increases on the surface within the recess. Accelerators tend to be smaller molecules and exhibit faster diffusion into recessed features, as compared to suppressors.

While not wishing to be bound by any theory or mechanism of action, it is believed that levelers (either alone or in combination with other bath additives) act as suppressing agents to counteract the depolarization effect associated with accelerators, especially in the field region and at the side walls of a feature. The leveler may locally increase the polarization/surface resistance of the substrate, thereby slowing the local electrodeposition reaction in regions where the leveler is present. The local concentration of levelers is determined to some degree by mass transport. Therefore levelers act principally on surface structures having geometries that protrude away from the surface. This action “smooths” the surface of the electrodeposited layer. It is believed that the leveler reacts or is consumed at the substrate surface at a rate that is at or near a diffusion limited rate, and therefore, a continuous supply of leveler is often beneficial in maintaining uniform plating conditions over time. Leveler compounds are generally classified as levelers based on their electrochemical function and impact and do not require specific chemical structure or formulation. However, levelers often contain one or more nitrogen, amine, imide or imidazole, and may also contain sulfur functional groups. Certain levelers include one or more five and six member rings and/or conjugated organic compound derivatives. Nitrogen groups may form part of the ring structure. In amine-containing levelers, the amines may be primary, secondary or tertiary alkyl amines. Furthermore, the amine may be an aryl amine or a heterocyclic amine. Example amines include, but are not limited to, dialkylamines, trialkylamines, arylalkylamines, triazoles, imidazole, triazole, tetrazole, benzimidazole, benzotriazole, piperidine, morpholines, piperazine, pyridine, oxazole, benzoxazole, pyrimidine, quonoline, and isoquinoline. Imidazole and pyridine may be especially useful. Leveler compounds may also include ethoxide groups. For example, the leveler may include a general backbone similar to that found in polyethylene glycol or polyethyelene oxide, with fragments of amine functionally inserted over the chain (e.g., Janus Green B). Example epoxides include, but are not limited to, epihalohydrins such as epichlorohydrin and epibromohydrin, and polyepoxide compounds. Polyepoxide compounds having two or more epoxide moieties joined together by an ether-containing linkage may be especially useful. Some leveler compounds are polymeric, while others are not. Example polymeric leveler compounds include, but are not limited to, polyethylenimine, polyamidoamines, and reaction products of an amine with various oxygen epoxides or sulfides. One example of a non-polymeric leveler is 6-mercapto-hexanol. Another example leveler is polyvinylpyrrolidone (PVP).

The use of suppressor, accelerator, and leveler, in combination, may allow deposition of copper structures without voids from the bottom-up while producing a relatively flat deposited surface. The exact identity/composition of the additive compounds are typically maintained as trade secrets by the additive suppliers, thus, information about the exact nature of these compounds is not publicly available.

The electroplating solution of the present disclosure, however, is free or substantially free of accelerator additives in the electroplating solution when depositing nanotwinned copper structures. As used herein, “substantially free of” may refer to a concentration of accelerators that is equal to or less than about 5 ppm. In some implementations, the a concentration of accelerator additives is between about 0 ppm and about 5 ppm, and a concentration of suppressor additives is between about 30 ppm and about 300 ppm. In some alternative implementations, the electroplating solution of the present disclosure may contain accelerator additives when an underlying base layer upon which the nanotwinned copper structure is deposited is highly oriented. In such instances, the concentration of accelerator additives may be equal to or greater than about 5 ppm, or between about 5 ppm and about 40 ppm.

The electroplating solution may be flowed into the plating cell to contact the surface of the substrate. The electroplating apparatus may be configured to enable flow of the electroplating solution in a direction towards or perpendicular to the surface of the substrate. In some implementations, the electroplating solution may be flowed from holes of a channeled ionically resistive element during electroplating. A flow rate or flow velocity of the electroplating solution may be controlled to promote formation of nanotwins in the nanotwinned copper structure. Lower flow rates making contact with the substrate during electroplating may promote a higher density of nanotwins than higher flow rates. In some implementations, the flow velocity of the electroplating solution is equal to or less than about 70 cm/s, or equal to or less than about 30 cm/s. In other words, the flow velocity can be between about 30 cm/s and about 70 cm/s. In some implementations, the flow rate of the electroplating solution is equal to or less than about 50 liters per minute, equal to or less than about 20 liters per minute, or between about 20 liters per minute and about 50 liters per minute.

In some implementations of the process 300, the substrate may be chemically pretreated prior to contacting the substrate with the electroplating solution. The chemical pretreatment may cause an increase in density of nanotwins when depositing the nanotwinned copper structure. In some implementations, the substrate is chemically pretreated by immersing in a solution with suppressor additives. In some implementations, the substrate is chemically pretreated by cleaning with acetone, acid, piranha solution, or some other suitable cleaning solution.

At block 320 of the process 300, a first current is applied to the substrate when the substrate is contacted with the electroplating solution to deposit a nanotwinned copper structure on the substrate, where the first current comprises a pulsed current waveform that alternates between a constant current and no current. During electroplating, current and/or voltage are supplied to the electroplating apparatus in a manner that causes copper to deposit on the substrate, which acts as a cathode. The applied current may be modulated during electroplating. The applied current may be provided by an electrical power source or power supply.

The nanotwinned copper structure may be deposited on the substrate by applying the first current that uses pulsed current deposition. The first current has a pulsed current waveform that alternates between a constant current (Iₒₙ) and no current (I_{off}). The first current provides a direct current (DC) having a current density that is between about 1 A/dm² and about 12 A/dm², between about 2 A/dm² and about 8 A/dm², or about 4 A/dm². The current density is controlled to promote formation of nanotwins in the nanotwinned copper structure. A minimum current density (e.g., 2 A/dm²) may be necessary to promote formation of nanotwins at an acceptable plating rate, and a maximum current density (e.g., 8 A/dm²) may inhibit formation of nanotwins.

A duration of no current (T_{off}) being applied is substantially greater than a duration of the constant current (Tₒₙ) being applied in the pulsed current waveform. In some implementations, the duration of no current is at least three times longer than a duration of the constant current. In some implementations, the duration of no current being applied can be between about 0.3 seconds and about 8 seconds, or between about 0.4 seconds and about 6 seconds, or between about 0.5 seconds and about 5 seconds. In some implementations, the duration of constant current being applied can be between about 0.05 seconds and about 2.5 seconds, between about 0.1 seconds and about 2 seconds, or between about 0.1 seconds and about 1.5 seconds. Examples of Tₒₙ/T_{off} for the pulsed current waveform may be 0.1/0.5, 0.2/1, 0.5/2, 1/4, or 1.5/6 with a current density of about 4 A/dm². Durations for Tₒₙ/T_{off} may be tuned to achieve a high density of nanotwins at an acceptable plating rate. An acceptable plating rate for sufficiently high throughput applications may be at least about 0.1 μm per minute, at least about 0.15 μm per minute, at least about 0.2 μm per minute, or at least about 0.5 μm per minute.

Cycles of alternating constant current and no current in the pulsed current waveform are repeated until a desired thickness of the nanotwinned copper structure is deposited. In some implementations, at least about 500 cycles are repeated, at least about 1000 cycles are repeated, at least about 2000 cycles are repeated, or at least about 3000 cycles are repeated. In some implementations, the thickness of the nanotwinned copper structure is at least a few micrometers. For example, the thickness of the nanotwinned copper structure deposited by the first current using the pulsed current waveform is at least about 1 μm, at least about 2 μm, and at least about 3 μm. In some implementations, the thickness of the nanotwinned copper structure deposited by the first current using the pulsed current waveform is up to about 3 μm for an increased density of nanotwins.

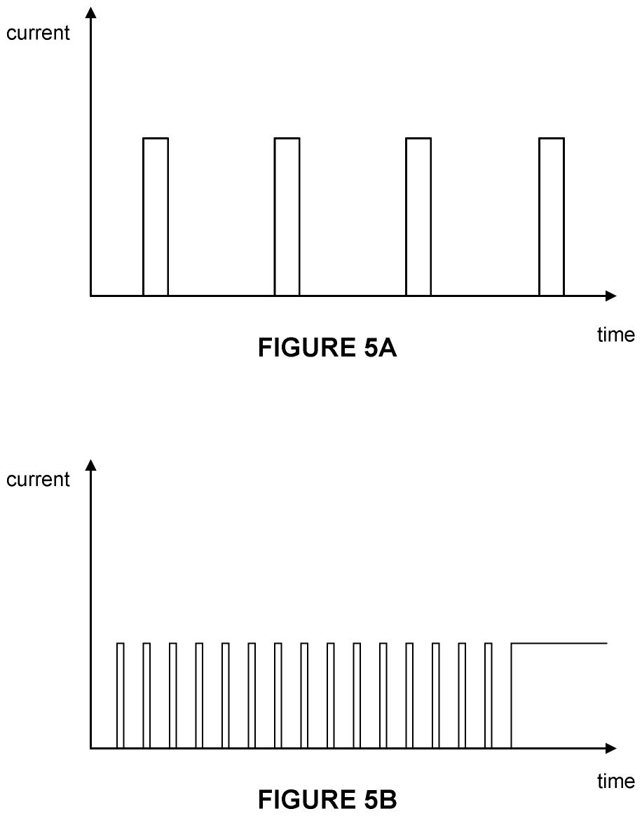

Without being limited by any theory, the pulsed current waveform facilitates growth of (111)-oriented nanotwinned crystal copper grains. FIGS. 4A-4C show cross-sectional schematic diagrams of copper grain structures in a sequence for forming nanotwins during electroplating according to some implementations. FIGS. 4A-4B illustrate a single plating cycle and FIG. 4C illustrates multiple plating cycles. In FIG. 4A, a constant current is applied for a duration of Tₒₙ during electroplating where the applied constant current drives the reaction of copper ions in the electroplating solution to copper metal. During application of the constant current, copper is deposited so that copper grain structures are oriented in various crystallographic orientations. Examples of crystallographic orientations of the copper grain structures include (110), (100), and (111). In FIG. 4B, no current is applied following application of the constant current for a duration of T_{off}. When no current is applied, copper atoms may rearrange and relax internal stresses, thereby allowing the copper grain structures to relax to their lowest energy states. As a result, the copper grain structures generally relax to crystallographic orientations of (111), which is more energetically favorable. Twinning occurs at the nanoscale as the internal stresses of the crystal structure relax. The duration of T_{off} is sufficiently long to permit nanotwinning. However, the duration of T_{off} cannot be excessively long to lower the plating rate below an acceptable throughput. In addition, the duration of T_{off} cannot be excessively long to expose the substrate to the electroplating solution for a prolonged period to cause degradation of various materials (e.g., polymer photoresist) to degrade. In FIG. 4C, multiple cycles that alternate between constant current and no current are performed. Each of the cycles is performed using a pulsing sequence Tₒₙ/T_{off}. Nanotwins grow in (111)-oriented copper grains and stack in a layer-by-layer manner along a [111] crystal axis, thereby forming a nanotwinned copper structure of a desired thickness.

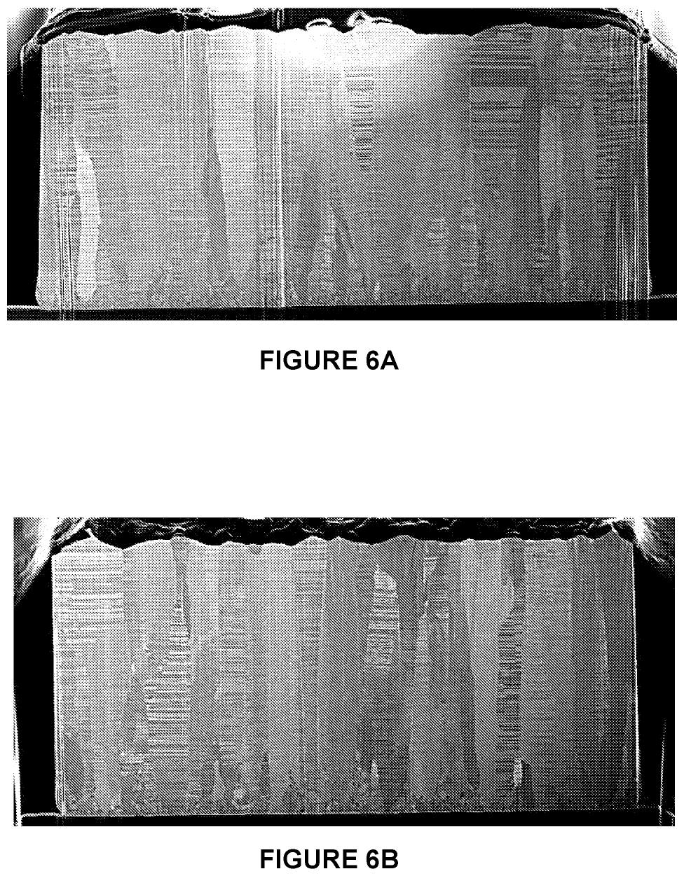

FIG. 5A shows a plot of applied current as a function of time in a pulsed current waveform for depositing a nanotwinned copper structure according to some implementations. The pulsed current waveform shows application of direct current alternating between a constant current and no current. The current density of the constant current, the duration of the constant current per cycle, and the duration of no current per cycle may be fine-tuned to achieve a high density of nanotwins in a deposited copper structure. For example, the current density of the constant current is about 4 A/dm², the duration of the constant current per cycle is about 0.1 seconds, and the duration of the no current per cycle is about 0.5 seconds. Such conditions in the pulsed current waveform enables formation of a high density of nanotwins.

Returning to FIG. 3, at block 330 of the process 300, a second current is optionally applied to the substrate when the substrate is contacted with the electroplating solution, where the second current comprises a constant current waveform. The first current may be applied to the substrate to deposit a first thickness of at least about 1 μm of the nanotwinned copper structure before applying the second current to deposit a second thickness of the nanotwinned copper structure. The constant current waveform provides a constant current having a current density between about 1 A/dm² and about 12 A/dm², between about 2 A/dm² and about 8 A/dm², or about 4 A/dm².

FIG. 5B shows a plot of applied current as a function of time in a pulsed current waveform followed by a constant current waveform for depositing a nanotwinned copper structure according to some implementations. The applied current shows a pulsed current waveform alternating between a constant current and no current, which is followed by a constant current waveform. A constant current of the constant current waveform may have a current density of about 4 A/dm², and the duration of the constant current may last until a desired thickness of a copper structure is deposited. Such conditions in the pulsed current waveform and constant current waveform lead to the formation of a high density of nanotwins.

A high density of nanotwins may surprisingly continue to form when transitioning from a pulsed current waveform to a constant current waveform. Thus, transitioning from a pulsed current waveform to a constant current waveform does not prevent formation of nanotwins. Typically, application of a constant current waveform does not result in nanotwinning in copper structures. However, application of a constant current waveform following application of a pulsed current waveform may produce nanotwinning in copper structures. Without being limited by any theory, nanotwinning in the nanotwinned copper structure may continue even with application of a constant current waveform because an underlying layer contains a plurality of (111)-oriented nanotwinned copper crystal grains. The underlying layer that contains the plurality of (111)-oriented nanotwinned copper crystal grains provides a stacking pattern that continues to propagate even upon transitioning from a pulsed current waveform to a constant current waveform.

Transitioning from a pulsed current waveform to a constant current waveform can occur after a first thickness of the nanotwinned copper structure is formed using the pulsed current waveform. In some implementations, the first thickness of the nanotwinned copper structure can be at least about 0.2 μm, at least about 0.5 μm, at least about 1 μm, at least about 3 μm, at least about 5 μm, between about 0.5 μm and about 10 μm, between about 1 μm and about 5 μm, or perhaps as little as about 0.1 μm. In some implementations, a greater thickness may provide a higher density of nanotwins, where a first thickness of 3 μm may provide better performance than a first thickness of 1 μm. The second thickness of the nanotwinned copper structure can be greater than the first thickness of the nanotwinned copper structure. The second thickness of the nanotwinned copper structure can be the difference between the desired thickness of the nanotwinned copper structure and the first thickness. For example, the second thickness can be 25 μm where a desired thickness of a copper pillar is 30 μm and 5μm of the copper pillar is deposited using a pulsed current waveform. The second thickness can be the remaining thickness of the nanotwinned copper structure, where the remaining thickness is deposited using a constant current waveform.

Plating a desired thickness of the nanotwinned copper structure may be too slow using a pulsed current waveform. Plating the second thickness of the nanotwinned copper structure using a constant current waveform can lead to an increased effective plating rate and an increased throughput when electroplating nanotwinned copper structures. In some implementations, an effective plating rate when depositing the nanotwinned copper structure using the first current (pulsed current waveform) and the second current (constant current waveform) is at least about 0.3 μm per minute, at least about 0.5 μm per minute, at least about 0.7 μm per minute, at least about 1 μm per minute, or between about 0.5 μm per minute and about 1 μm per minute.

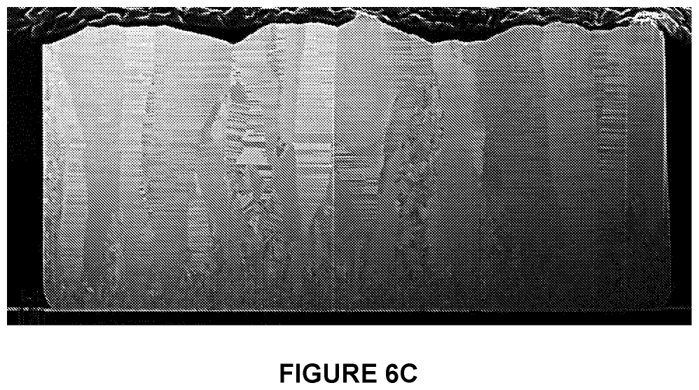

FIG. 6A shows a cross-section SEM image of a 30 μm thick copper pillar according to some implementations. The copper pillar is deposited by applying a pulsed current waveform for about 3 μm. The pulsed current waveform applies multiple cycles of a constant current having a current density of 4 A/dm² for 0.1 seconds followed by no current for about 0.4 seconds. The remaining thickness is deposited by applying a constant current waveform. As shown in FIG. 6A, a high density of nanotwins is grown in the copper pillar with a relatively small initiation layer. The “initiation layer” is observed where grains are randomly oriented and non-nanotwinned at the onset of deposition.

FIG. 6B shows a cross-section SEM image of a 30 μm thick copper pillar according to some implementations. The copper pillar is deposited by applying a pulsed current waveform for about 1 μm. The pulsed current waveform applies multiple cycles of a constant current having a current density of 4 A/dm² for 0.1 seconds followed by no current for about 0.4 seconds. The remaining thickness is deposited by applying a constant current waveform. As shown in FIG. 6B, a high density of nanotwins is grown in the copper pillar with a relatively small initiation layer.

FIG. 6C shows a cross-section SEM image of a 30 μm thick copper pillar according to some implementations. The copper pillar is deposited by applying a constant current waveform having a current density of 4 A/dm². As shown in FIG. 6C, sporadic regions of non-nanotwinned copper extends beyond a few microns and up to at least 20 μm into the bulk of the copper pillar. Some nanotwinning may be observed in the copper pillar, but a poor initiation layer results in a lot of non-nanotwinned regions.

Returning to the process 300 of FIG. 3, various electroplating conditions may be controlled to influence formation of nanotwins in the nanotwinned copper structure. In some implementations, control of substrate temperature can increase or decrease the density of nanotwins. Too high of a temperature can reduce the density of nanotwins, and too low of a temperature can reduce the density of nanotwins. In some implementations, a substrate temperature can be between about 10° C. and about 45° C., or between about 20° C. and about 35° C. Without being limited by any theory, a lower temperature can reduce spacing between nanotwins, thereby increasing density.

The process 300 may be used to fabricate copper structures of a variety of packaging features in WLP or other advanced packaging designs. Some of the packaging features may include but are not limited to copper wires, redistribution lines (RDL), and pillars of different sizes. Such pillars may include: micro-pillars, standard pillars, integrated high density fan-out structures, and megapillars. In some implementations, the nanotwinned copper structure deposited by the process 300 may be a copper pillar, redistribution layer, or under-bump metallization. Dimensions of such nanotwinned copper structures may be on the order of a few to several microns. The nanotwinned copper structures described in the present disclosure may be deposited for a variety of different aspect ratios and sizes. In some implementations, the nanotwinned copper structure has a thickness of at least about 5 μm.

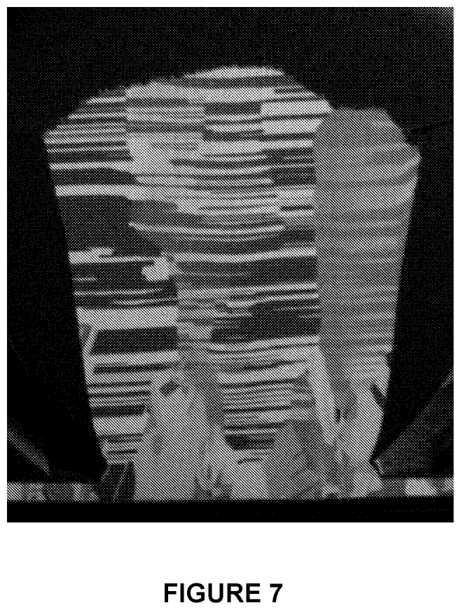

FIG. 7 shows a cross-section SEM image of a copper redistribution layer with a high density of nanotwinned grain structures. The copper redistribution layer has a thickness of 5 μm and is formed using a pulsed current waveform. An example of a pulsed current is described in FIG. 5A. Nanotwins in the copper redistribution layer can be observed by long vertical columnar grain structures and several patterns of horizontal twins stacked on top of each other. The horizontal twins can be observed by light and dark lines spanning across the grain structures.

Returning to the process 300 of FIG. 3, the nanotwinned copper structure may be formed by depositing on a highly-oriented base layer. Where the nanotwinned copper structure is deposited on a highly-oriented base layer, electroplating conditions for depositing the nanotwinned copper structure may be different than when depositing on other types of layers. In some implementations, the electroplating solution may be different when depositing on a highly-oriented base layer than when depositing on other types of layers. In some implementations, the applied current waveform may be different when depositing on a highly-oriented base layer than when depositing on other types of layers.

The highly-oriented base layer may be an underlying layer on which the nanotwinned copper structure is deposited. A highly-oriented base layer may share crystallographic properties similar to the nanotwinned copper structure. The crystallographic properties may include but are not limited to orientation and shape of grain structures in the underlying base layer. In some implementations, the base layer may be considered “highly-oriented” where it includes a plurality of columnar grain structures. In some implementations, the base layer may be considered “highly-oriented” where it includes a plurality of <111> crystal grain structures in a face-centered cubic structure. Without being limited by any theory, the orientation of the grain structures creates a stacking arrangement that promotes the growth of (111)-oriented nanotwins.

In some implementations, the highly-oriented base layer is a diffusion barrier layer having a plurality of columnar grain structures. Examples of materials in a diffusion barrier layer include but are not limited to titanium (Ti), titanium tungsten (TiW), titanium nitride (TiN), tantalum (Ta), and tantalum nitride (TaN). In some implementations, the highly-oriented base layer is a copper seed layer having a plurality of <111> crystal grain structures. Typically, nanotwinned copper structures are deposited using an electroplating solution that is free or at least substantially free of an accelerator additive. In other words, the presence of an accelerator additive ordinarily inhibits the formation of nanotwins in copper structures. However, when depositing on a highly-oriented base layer such as a diffusion barrier layer with columnar grain structures or a copper seed layer with <111> crystal grain structures, nanotwinned copper structures may be deposited using an electroplating solution that contains an accelerator additive. The presence of accelerator additives in electroplating solutions may be useful in a variety of electroplating operations and tends to promotes bottom-up void-free filling of features. Thus, copper structures with a high density of nanotwins may be deposited using accelerator additives when an underlying base layer is highly-oriented.

In some implementations, where the highly-oriented base layer is a diffusion layer having a plurality of columnar grain structures or a copper seed layer having a plurality of <111> crystal grain structures, nanotwinned copper structures are deposited using a constant current waveform. In some implementations, where the highly-oriented base layer is a diffusion layer having a plurality of columnar grain structures or a copper seed layer having a plurality of <111> crystal grain structures, nanotwinned copper structures are deposited using a pulsed current waveform that is different than the first current at block 320.

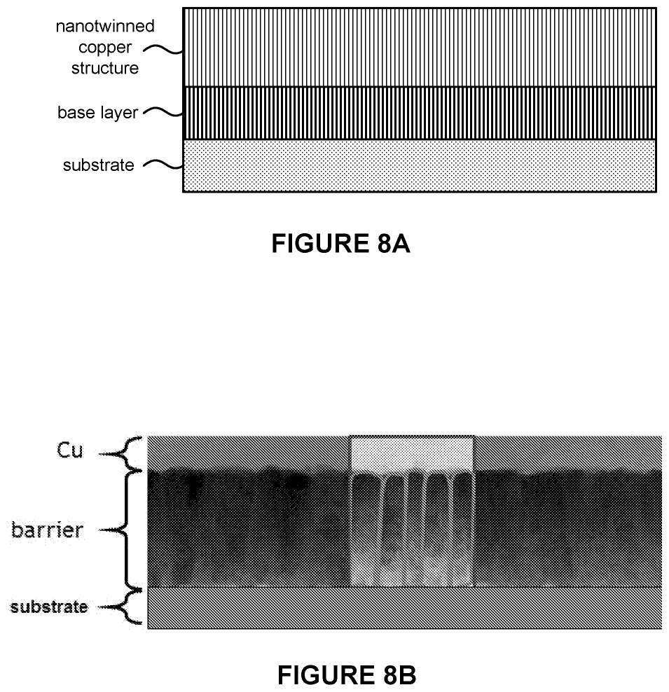

FIG. 8A shows a cross-sectional schematic of a nanotwinned copper structure deposited on a base layer according to some implementations. A base layer is formed on a substrate, where the base layer may be highly oriented with a particular crystal structure and orientation of grains. The crystal structure and orientation of the grains may promote growth of (111)-oriented nanotwins in copper electroplating when an electroplating solution contains accelerator additives. For example, the base layer may include a plurality of columnar grain structures or a plurality of <111> crystal grain structures. In some implementations, the base layer is a diffusion barrier layer having a plurality of columnar grain structures or is a copper seed layer having a plurality of <111> crystal grain structures. As shown in FIG. 8A, a nanotwinned copper structure is deposited on the base layer. A high density of nanotwins in a copper structure may be formed when deposited on a highly-oriented base layer regardless of whether the electroplating solution contains accelerator additives or not.

FIG. 8B shows a cross-section transmission electron microscopy (TEM) image of a nanotwinned copper structure deposited on a highly columnar diffusion barrier layer. Columnar grain structures may be observed using a suitable microscopy-based technique. The TEM image of the diffusion barrier layer shows vertically-oriented grain structures adjacent to one another, where outlines of the grain structures are marked-up in FIG. 8B to indicate the shape of the grain structures. A nanotwinned copper structure is deposited on the highly columnar diffusion barrier layer, where the nanotwinned copper structure is deposited using bis-(3-sulfopropyl) disulfide (SPS) as an accelerator additive in an electroplating solution.

Returning to the process 300 of FIG. 3, the nanotwinned copper structure may be formed by depositing on a non-copper seed layer. The non-copper seed layer may also be referred to as a “non-copper seed,” “non-copper liner,” or “non-copper liner layer.” The non-copper seed layer may include an electrically conductive material such as ruthenium (Ru), gold (Au), or cobalt (Co). The electrically conductive material may be more electrically resistive than copper. In some implementations, the non-copper seed layer includes cobalt. The nanotwinned copper structure may be deposited on a cobalt seed layer without depositing on a copper seed layer. This shows that the nanotwinned copper structure can be deposited on foreign metallic material that does not necessarily share the same crystallographic properties as copper. In some implementations, the nanotwinned copper structure may be deposited on the non-copper seed layer using a pulsed current waveform or a pulsed current waveform followed by a constant current waveform. In some implementations, the nanotwinned copper structure may be deposited on the non-copper seed layer using an electroplating solution free of or substantially free of an accelerator additive. Nanotwinned copper structures may be deposited on seed layers, regardless of whether the seed layers are copper seed layers or cobalt seed layers, using electroplating conditions described earlier in the process 300.

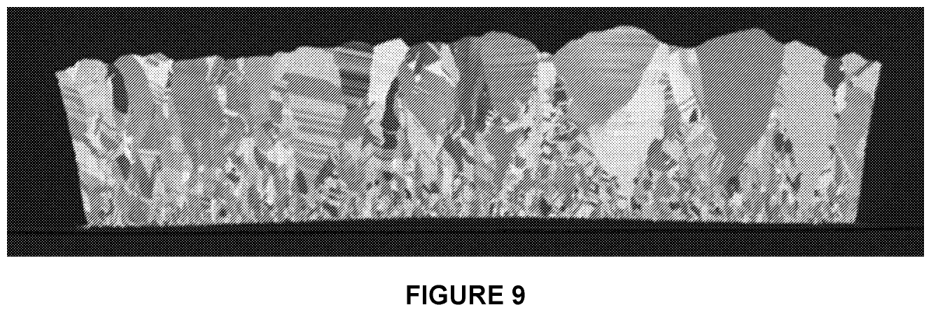

FIG. 9 shows a cross-section SEM image of a copper redistribution layer having a high density of nanotwinned grain structures on a cobalt seed layer. A high density of nanotwins is observed in columnar grain structures in the SEM image. The copper redistribution layer has a width of 20 μm and a thickness of 5 μm. The copper redistribution layer having high density of nanotwins is deposited on a cobalt seed layer. The copper redistribution layer is deposited using a pulsed current waveform that alternates between a constant current and no current, where a duration of the constant current being applied per cycle is 0.1 seconds and a duration of no current being applied per cycle is 0.5 seconds. The current density of the constant current in the pulsed current waveform is 4 A/dm².

### Apparatus for Electroplating

Many apparatus configurations may be used in accordance with the implementations described herein. FIG. 10 shows a schematic diagram of an example of an electroplating cell in which electroplating may occur according to some implementations. Often, an electroplating apparatus includes one or more electroplating cells in which the substrates (e.g., wafers) are processed. Only one electroplating cell is shown in FIG. 10 to preserve clarity. To optimize bottom-up electroplating, additives may be added to the electroplating solution (e.g., electrolyte); however, an electroplating solution with accelerators may inhibit growth of nanotwins in copper structures unless deposited on a highly-oriented base layer.

An implementation of an electroplating apparatus 1001 is shown in FIG. 10. A plating bath 1003 contains the electroplating solution (having a composition as discussed herein), which is shown at a level 1005. A substrate 1007 is immersed into the electroplating solution and is held by, e.g., a “clamshell” substrate holder 1009, mounted on a rotatable spindle 1011, which allows rotation of clamshell substrate holder 1009 together with the substrate 1007. A general description of a clamshell-type plating apparatus having aspects suitable for use with this invention is described in detail in U.S. Pat. No. 6,156,167 issued to Patton et al., and U.S. Pat. No. 6,800,187 issued to Reid et al., which are incorporated by reference in their entireties and for all purposes.

An anode 1013 is disposed below the substrate 1007 within the plating bath 1003 and is separated from the substrate region by a membrane 1015, preferably an ion selective membrane. For example, Nafion™ cationic exchange membrane (CEM) may be used. The region below the anodic membrane is often referred to as an “anode chamber.” The ion-selective anode membrane 1015 allows ionic communication between the anodic and cathodic regions of the plating cell, while preventing the particles generated at the anode from entering the proximity of the substrate 1007 and contaminating it. The anode membrane is also useful in redistributing current flow during the plating process and thereby improving the plating uniformity. Detailed descriptions of suitable anodic membranes are provided in U.S. Pat. Nos. 6,126,798 and 6,569,299 issued to Reid et al., both incorporated by reference in their entireties and for all purposes. Ion exchange membranes, such as cationic exchange membranes, are especially suitable for these applications. These membranes are typically made of ionomeric materials, such as perfluorinated co-polymers containing sulfonic groups (e.g. Nafion™), sulfonated polyimides, and other materials known to those of skill in the art to be suitable for cation exchange. Selected examples of suitable Nafion™ membranes include N324 and N424 membranes available from Dupont de Nemours Co.

During plating the ions from the electroplating solution are deposited on the substrate 1007. The metal ions must diffuse through the diffusion boundary layer and into the TSV hole or other feature. A typical way to assist the diffusion is through convection flow of the electroplating solution provided by a pump 1017. Additionally, a vibration agitation or sonic agitation member may be used as well as substrate rotation. For example, a vibration transducer 1008 may be attached to the clamshell substrate holder 1009.

The electroplating solution is continuously provided to plating bath 1003 by the pump 1017. Generally, the electroplating solution flows upwards through an anode membrane 1015 and a diffuser plate 1019 to the center of substrate 1007 and then radially outward and across substrate 1007. The electroplating solution also may be provided into the anodic region of the bath from the side of the plating bath 1003. The electroplating solution then overflows plating bath 1003 to an overflow reservoir 1021. The electroplating solution is then filtered (not shown) and returned to pump 1017 completing the recirculation of the electroplating solution. In certain configurations of the plating cell, a distinct electrolyte is circulated through the portion of the plating cell in which the anode is contained while mixing with the main electroplating solution is prevented using sparingly permeable membranes or ion selective membranes.

A reference electrode 1031 is located on the outside of the plating bath 1003 in a separate chamber 1033, which chamber is replenished by overflow from the main plating bath 1003. Alternatively, in some implementations, the reference electrode 1031 is positioned as close to the substrate surface as possible, and the reference electrode chamber is connected via a capillary tube or by another method, to the side of the substrate 1007 or directly under the substrate 1007. In some implementations, the electroplating apparatus 1001 further includes contact sense leads that connect to the substrate periphery and which are configured to sense the potential of the metal seed layer at the periphery of the substrate 1007 but do not carry any current to the substrate 1007.

A DC power supply 1035 can be used to control current flow to the substrate 1007. The power supply 1035 has a negative output lead 1039 electrically connected to substrate 1007 through one or more slip rings, brushes and contacts (not shown). The positive output lead 1041 of power supply 1035 is electrically connected to an anode 1013 located in plating bath 1003. The power supply 1035, a reference electrode 1031, and a contact sense lead (not shown) can be connected to a system controller 1047, which allows, among other functions, modulation of current and potential provided to the elements of electroplating cell. For example, the controller 1047 may allow electroplating in potential-controlled and current-controlled regimes. The controller 1047 may include program instructions specifying current and voltage levels that need to be applied to various elements of the plating cell, as well as times at which these levels need to be changed. When forward current is applied, the power supply 1035 biases the substrate 1007 to have a negative potential relative to anode 1013. This causes an electrical current to flow from anode 1013 to the substrate 1007, and an electrochemical reduction (e.g. Cu²⁺+2e⁻=Cu⁰) occurs on the substrate surface (the cathode), which results in the deposition of the electrically conductive layer (e.g. copper) on the surfaces of the substrate 1007. An inert anode 1014 may be installed below the substrate 1007 within the plating bath 1003 and separated from the substrate region by the membrane 1015.

The electroplating apparatus 1001 may also include a heater 1045 for maintaining the temperature of the electroplating solution at a specific level. The electroplating solution may be used to transfer the heat to the other elements of the plating bath 1003. For example, when a substrate 1007 is loaded into the plating bath 1003, the heater 1045 and the pump 1017 may be turned on to circulate the electroplating solution through the electroplating apparatus 1001, until the temperature throughout the electroplating apparatus 1001 becomes substantially uniform. In some implementations, the heater 1045 is connected to the system controller 1047. The system controller 1047 may be connected to a thermocouple to receive feedback of the electroplating solution temperature within the electroplating apparatus 1001 and determine the need for additional heating.

The electrodeposition methods disclosed herein can be described in reference to, and may be employed in the context of, various electroplating tool apparatuses. One example of a plating apparatus that may be used according to the embodiments herein is the Lam Research Sabre® tool. Electrodeposition, including substrate immersion, and other methods disclosed herein can be performed in components that form a larger electrodeposition apparatus.

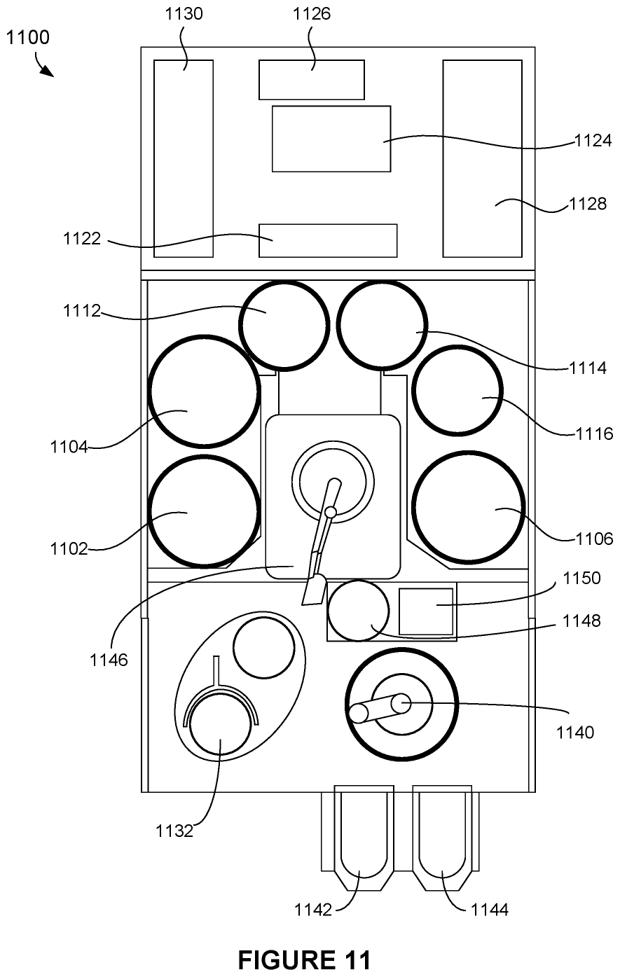

FIG. 11 shows a schematic of a top view of an example electrodeposition apparatus according to some implementations. The electrodeposition apparatus 1100 can include three separate electroplating modules 1102, 1104, and 1106. The electrodeposition apparatus 1100 can also include three separate modules 1112, 1114, and 1116 configured for various process operations. For example, in some embodiments, one or more of modules 1112, 1114, and 1116 may be a spin rinse drying (SRD) module. In other embodiments, one or more of the modules 1112, 1114, and 1116 may be post-electrofill modules (PEMs), each configured to perform a function, such as edge bevel removal, backside etching, and acid cleaning of substrates after they have been processed by one of the electroplating modules 1102, 1104, and 1106.

The electrodeposition apparatus 1100 includes a central electrodeposition chamber 1124. The central electrodeposition chamber 1124 is a chamber that holds the chemical solution used as the electroplating solution in the electroplating modules 1102, 1104, and 1106. The electrodeposition apparatus 1100 also includes a dosing system 1126 that may store and deliver additives for the electroplating solution. A chemical dilution module 1122 may store and mix chemicals to be used as an etchant. A filtration and pumping unit 1128 may filter the electroplating solution for the central electrodeposition chamber 1124 and pump it to the electroplating modules.

A system controller 1130 provides electronic and interface controls required to operate the electrodeposition apparatus 1100. The system controller 1130 (which may include one or more physical or logical controllers) controls some or all of the properties of the electrodeposition apparatus 1100. The system controller 1130 typically includes one or more memory devices and one or more processors. The processor may include a central processing unit (CPU) or computer, analog and/or digital input/output connections, stepper motor controller boards, and other like components. Instructions for implementing appropriate control operations as described herein may be executed on the processor. These instructions may be stored on the memory devices associated with the system controller 1130 or they may be provided over a network. In certain embodiments, the system controller 1130 executes system control software.

The system control software in the electrodeposition apparatus 1100 may include instructions for controlling the timing, mixture of electrolyte components (including the concentration of one or more electrolyte components), inlet pressure, plating cell pressure, plating cell temperature, substrate temperature, current and potential applied to the substrate and any other electrodes, substrate position, substrate rotation, and other parameters of a particular process performed by the electrodeposition apparatus 1100. The system control logic may also include instructions for electroplating under conditions that are tailored to be appropriate for depositing nanotwinned copper structures. For example, the system control logic may be configured to provide a pulsed current waveform and/or a pulsed current waveform followed by a constant current waveform. Further, the system control logic may be configured to provide an electroplating solution to the substrate that is free of or substantially free of accelerator additives. The system control logic may be configured to provide the electroplating solution to the substrate at a relatively low flow rate. System control logic may be configured in any suitable way. For example, various process tool component sub-routines or control objects may be written to control operation of the process tool components necessary to carry out various process tool processes. System control software may be coded in any suitable computer readable programming language. The logic may also be implemented as hardware in a programmable logic device (e.g., an FPGA), an ASIC, or other appropriate vehicle.

In some implementations, system control logic includes input/output control (IOC) sequencing instructions for controlling the various parameters described above. For example, each phase of an electroplating process may include one or more instructions for execution by the system controller 1130. The instructions for setting process conditions for an immersion process phase may be included in a corresponding immersion recipe phase. In some embodiments, the electroplating recipe phases may be sequentially arranged, so that all instructions for an electroplating process phase are executed concurrently with that process phase.

The control logic may be divided into various components such as programs or sections of programs in some implementations. Examples of logic components for this purpose include a substrate positioning component, an electrolyte composition control component, a pressure control component, a heater control component, and a potential/current power supply control component.

In some implementations, there may be a user interface associated with the system controller 1130. The user interface may include a display screen, graphical software displays of the apparatus and/or process conditions, and user input devices such as pointing devices, keyboards, touch screens, microphones, etc.

In some implementations, parameters adjusted by the system controller 1130 may relate to process conditions. Non-limiting examples include bath conditions (temperature, composition, and flow rate), substrate position (rotation rate, linear (vertical) speed, angle from horizontal) at various stages, etc. These parameters may be provided to the user in the form of a recipe, which may be entered utilizing the user interface.

Signals for monitoring the process may be provided by analog and/or digital input connections of the system controller 1130 from various process tool sensors. The signals for controlling the process may be output on the analog and digital output connections of the process tool. Non-limiting examples of process tool sensors that may be monitored include mass flow controllers, pressure sensors (such as manometers), thermocouples, optical position sensors, etc. Appropriately programmed feedback and control algorithms may be used with data from these sensors to maintain process conditions.

In one implementation, the instructions can include inserting the substrate in a substrate holder, tilting the substrate, biasing the substrate during immersion, and electrodepositing a nanotwinned copper structure on a substrate.

A hand-off tool 1140 may select a substrate from a substrate cassette such as the cassette 1142 or the cassette 1144. The cassettes 1142 or 1144 may be front opening unified pods (FOUPs). A FOUP is an enclosure designed to hold substrates securely and safely in a controlled environment and to allow the substrates to be removed for processing or measurement by tools equipped with appropriate load ports and robotic handling systems. The hand-off tool 1140 may hold the substrate using a vacuum attachment or some other attaching mechanism.

The hand-off tool 1140 may interface with a substrate handling station 1132, the cassettes 1142 or 1144, a transfer station 1150, or an aligner 1148. From the transfer station 1150, a hand-off tool 1146 may gain access to the substrate. The transfer station 1150 may be a slot or a position from and to which hand-off tools 1140 and 1146 may pass substrates without going through the aligner 1148. In some implementations, however, to ensure that a substrate is properly aligned on the hand-off tool 1146 for precision delivery to an electroplating module, the hand-off tool 1146 may align the substrate with an aligner 1148. The hand-off tool 1146 may also deliver a substrate to one of the electroplating modules 1102, 1104, or 1106 or to one of the three separate modules 1112, 1114, and 1116 configured for various process operations.

An example of a process operation according to the methods described above may proceed as follows: (1) electrodeposit a nanotwinned copper structure onto a substrate in the electroplating module 1104; (2) rinse and dry the substrate in SRD in module 1112; and, (3) perform edge bevel removal in module 1114.

An apparatus configured to allow efficient cycling of substrates through sequential plating, rinsing, drying, and PEM process operations may be useful for implementations for use in a manufacturing environment. To accomplish this, the module 1112 can be configured as a spin rinse dryer and an edge bevel removal chamber. With such a module 1112, the substrate would only need to be transported between the electroplating module 1104 and the module 1112 for the copper plating and EBR operations.

In some implementations, a controller (e.g., system controller 1130) is part of a system, which may be part of the above-described examples. Such systems can comprise semiconductor processing equipment, including a processing tool or tools, chamber or chambers, a platform or platforms for processing, and/or specific processing components (a pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of electroplating solution, temperature settings (e.g., heating and/or cooling), pressure settings, power settings, current waveform settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of WLP features of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

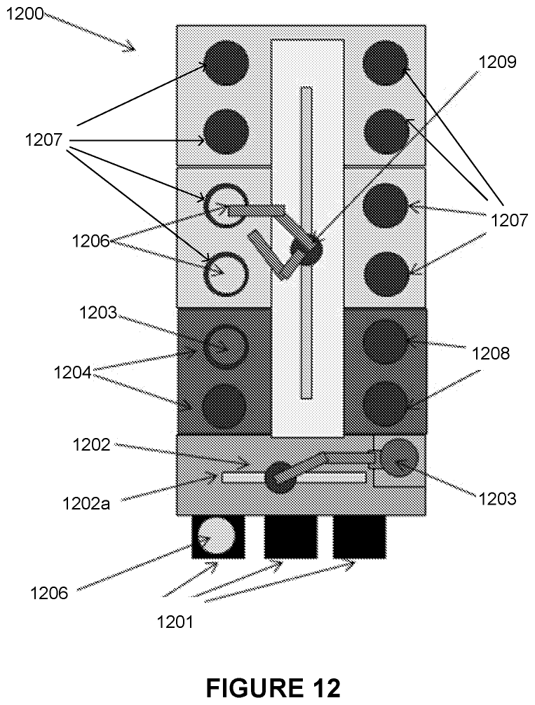

An alternative implementation of an electrodeposition apparatus 1200 is schematically illustrated in FIG. 12. In this embodiment, the electrodeposition apparatus 1200 has a set of electroplating cells 1207, each containing an electroplating bath, in a paired or multiple “duet” configuration. In addition to electroplating per se, the electrodeposition apparatus 1200 may perform a variety of other electroplating related processes and sub-steps, such as spin-rinsing, spin-drying, metal and silicon wet etching, electroless deposition, pre-wetting and pre-chemical treating, reducing, annealing, photoresist stripping, and surface pre-activation, for example. The electrodeposition apparatus 1200 is shown schematically looking top down in FIG. 12, and only a single level or “floor” is revealed in the figure, but it is to be readily understood by one having ordinary skill in the art that such an apparatus, e.g. the Sabre® 3D tool, can have two or more levels “stacked” on top of each other, each potentially having identical or different types of processing stations.

Referring once again to FIG. 12, the substrates 1206 that are to be electroplated are generally fed to the electrodeposition apparatus 1200 through a front end loading FOUP 1201 and, in this example, are brought from the FOUP to the main substrate processing area of the electrodeposition apparatus 1200 via a front-end robot 1202 that can retract and move a substrate 1206 driven by a spindle 1203 in multiple dimensions from one station to another of the accessible stations—two front-end accessible stations 1204 and also two front-end accessible stations 1208 are shown in this example. The front-end accessible stations 1204 and 1208 may include, for example, pre-treatment stations, and spin rinse drying (SRD) stations. Lateral movement from side-to-side of the front-end robot 1202 is accomplished utilizing robot track 1202a. Each of the substrates 1206 may be held by a cup/cone assembly (not shown) driven by a spindle 1203 connected to a motor (not shown), and the motor may be attached to a mounting bracket 1209. Also shown in this example are the four “duets” of electroplating cells 1207, for a total of eight electroplating cells 1207. The electroplating cells 1207 may be used for electroplating copper for the copper containing structure and electroplating solder material for the solder structure. A system controller (not shown) may be coupled to the electrodeposition apparatus 1200 to control some or all of the properties of the electrodeposition apparatus 1200.

The system controller may be programmed or otherwise configured to execute instructions according to processes described earlier herein.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., wafer, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Conclusion

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims.

It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of depositing a nanotwinned copper structure, the method comprising:
contacting a surface of a substrate with an electroplating solution; and
applying a first current to the substrate when the substrate is contacted with the electroplating solution to deposit a nanotwinned copper structure on the substrate, wherein the first current comprises a pulsed current waveform that alternates between a constant current and no current.

2. The method of claim 1, wherein the nanotwinned copper structure comprises a plurality of (111)-oriented nanotwinned crystal copper grains.

3. The method of claim 1, wherein a duration of no current being applied in the pulsed current waveform is at least three times longer than a duration of constant current being applied in the pulsed current waveform.

4. The method of claim 1, wherein the pulsed current waveform alternates between the constant current being applied for a duration between about 0.1 seconds and about 2 seconds, and no current being applied for a duration between about 0.4 seconds and about 6 seconds.

5. The method of claim 1, wherein the constant current of the pulsed current waveform has a current density between about 2 A/dm² and about 8 A/dm².

6. The method of claim 1, wherein the electroplating solution is free of or substantially free of an accelerator additive.

7. The method of claim 1, wherein the pulsed current waveform includes a plurality of cycles alternating between the constant current and no current to deposit the nanotwinned copper structure having a thickness of at least 5 μm.

8. The method of claim 1, further comprising:
applying a second current to the substrate when the substrate is contacted with the electroplating solution, wherein the second current comprises a constant current waveform.

9. The method of claim 8, wherein the first current is applied to the substrate to deposit a first thickness of at least about 1 μm of the nanotwinned copper structure, and wherein the second current is applied to the substrate to deposit a second thickness of the nanotwinned copper structure after the first thickness is deposited.

10. The method of claim 1, wherein the substrate comprises a diffusion barrier layer on which the nanotwinned copper structure is deposited, the diffusion barrier layer having a plurality of columnar grain structures.

11. The method of claim 10, wherein the electroplating solution includes an accelerator additive.

12. The method of claim 1, wherein the substrate comprises a copper seed layer on which the nanotwinned copper structure is deposited, the copper seed layer having a plurality of <111> crystal grain structures.

13. The method of claim 12, wherein the electroplating solution includes an accelerator additive.

14. The method of claim 1, wherein the substrate comprises a cobalt seed layer on which the nanotwinned copper structure is deposited.

15. The method of claim 1, wherein contacting the substrate with the electroplating solution occurs at a flow rate of between about 30 cm/s and about 70 cm/s.

16. The method of claim 1, wherein the nanotwinned copper structure is a copper pillar, redistribution layer, or under bump metallization.

17. An apparatus comprising:
an electroplating cell for holding an electroplating solution;
a substrate holder for supporting a substrate during electroplating;
a power supply for applying current to the substrate during electroplating; and
a controller configured with instructions for performing the following operations:
contact a surface of a substrate with the electroplating solution; and
apply a first current to the substrate when the substrate is contacted with the electroplating solution to deposit a nanotwinned copper structure on the substrate, wherein the first current comprises a pulsed current waveform that alternates between a constant current and no current.

18. The apparatus of claim 17, a duration of no current being applied in the pulsed current waveform is at least three times longer than a duration of constant current being applied in the pulsed current waveform.

19. The apparatus of claim 17, wherein the electroplating solution is free of or substantially free of an accelerator additive.

20. The apparatus of claim 17, wherein the controller is further configured with instructions for performing the following operation:
apply a second current to the substrate when the substrate is contacted with the electroplating solution, wherein the second current comprises a constant current waveform.

21. The apparatus of claim 17, wherein the substrate comprises a base layer on which the nanotwinned copper structure is deposited, the base layer being a diffusion barrier layer having a plurality of columnar grain structures or a copper seed layer having a plurality of <111> crystal grains.
